(19) United States
(12) Patent Application Publication
(10) Pub. No.: US 2006/0292747 A1
(43) Pub. Date: Dec. 28, 2006

(54) Top-surface-mount power light emitter with integral heat sink

(76) Inventor: Ban P. Loh, Durham, NC (US)

Correspondence Address: HARNESS, DICKEY & PIERCE, P.L.C., P.O. BOX 8910, RESTON, VA, 20195, US

(21) Appl. No.: 11/168,018

(22) Filed: Jun. 27, 2005

(51) Int. Cl. H01L 21/00; H01L 23/48

(52) U.S. Cl. 438/116; 257/749

(57) ABSTRACT

A light emitting apparatus is disclosed. The light emitting apparatus includes a substrate, a heat sink, a dielectric layer, conductive traces, a reflector, and at least one photonic device. The substrate has a top surface and a bottom surface, a portion of the top surface defining a mounting pad. The heat sink is equipped with cooling fins to cool the substrate. The conductive traces are on the top surface of the substrate and extend from the mounting pad to a side edge of the substrate. The reflector is attached to the top surface of the substrate. The reflector surrounds the mounting pad partially covering the top surface of the substrate. The photonic device is attached to the substrate at the mounting pad, the photonic device connected to at least one conductive trace. The light emitting apparatus can be mounted on a board having connection traces. The connection traces of the board are aligned with the conductive trace of the light emitting apparatus to effect electrical connection.

### BACKGROUND

The present invention relates to the field of light emitting device packages, and more particularly to top-mount light emitting packages with heat sink.

Light emitting devices such as light emitting diode (LED) packages are becoming increasingly popular components for a wide variety of applications. For example, LED packages are being used in greater numbers in products such as computer and information display systems, and even in automobile lighting applications.

In these applications, often, LED packages are soldered on top surface of a printed circuit boards (PCBs) or other substrate or backing material. Then, the top surface, including the LED packages, is covered with an optical or electrical panel. Such design allows for projection of light from the LED packages from the top surface of the PCB toward the optical or electrical panel.

Mounting the LED packages on the top surface of the PCB leads to a number of shortcomings. For example, the LED packages increases distance between the PCB and the optical or electrical panel. Further, heat generated by the LED packages is trapped between the PCB and the optical or electrical panel. Also, to replace an LED package, the PCB and the optical or electrical panel need be separated.

Consequently, there remains a need for an improved LED package and an improved design for providing light to optical or electrical panel overcomes or alleviates the shortcomings of the prior art devices.

### SUMMARY

The need is met by the present invention. In a first embodiment of the present invention, an apparatus includes a substrate, a plurality of conductive traces on the substrate, a reflector attached to the substrate, at least one photonic device on the substrate, and heat sink attached to the substrate. The substrate has a top surface and a bottom surface, a portion of the top surface defining a mounting pad. The conductive traces are on the top surface of the substrate, the conductive traces extending from the mounting pad to a side edge of the substrate and the conductive traces including electrically conductive material. The reflector is attached to the top surface of the substrate, the reflector surrounding the mounting pad while leaving other portions of the top surface of the substrate and portions of the conductive traces exposed, the reflector partially defining an optical cavity. The photonic device is attached to at least one conductive trace at the mounting pad. The heat sink is attached to the bottom portion of or is an integral portion of the substrate.

The photonic device can be a light emitting diode (LED) or laser. Further, the photonic device is wire bonded to at least one conductive trace. The substrate is made of thermally conductive material, for example, metal Aluminum (Al), Copper (Cu); in which case a dielectric layer is coated on its surface prior to deposition of electrical traces Alternatively, the substrate can be made from a high temperature plastics, for example, Polyphthalamide, Polyimide or Liquid Crystal Polymer (LCP) which are filled with thermal efficient material such as ceramics or graphite or optical reflective material such as Titanium dioxide or any combinations of these.

The optical cavity can be filled with encapsulant. A lens is placed in contact with the encapsulant thereby optically coupled to the photonic device. The encapsulant may include diffusants, phosphors, or both. For example, the encapsulant can include Titanium dioxide or Barium Sulfate. The phosphor material that absorbs light having a first wavelength and emits light having a second wavelength. The top surface is optically reflective to minimize loss of light by absorption. The reflector includes an optically reflective surface surrounding the optical cavity. The optically reflective surface can include diffusion grating. The conductive traces can be any conductive metal such as, for example, silver.

In a second embodiment of the present invention, a method of fabricating an apparatus is disclosed. First, a substrate is provided, the substrate having a top surface and a bottom surface, a portion of the top surface defining a mounting pad, the substrate having conductive traces on the top surface. Then, at least one photonic device is attached on the mounting pad, the photonic device in contact with at least one conductive trace. Next, a reflector is attached on the top surface of the substrate, the reflector surrounding the mounting pad and partially defining an optical cavity.

A heat sink is formed as an integral portion of the substrate or is an element attached to the bottom surface of the substrate. The optical cavity can be filled with encapsulant. A lens may be attached on the reflector, the encapsulant, or both.

The step of manufacturing substrate (Aluminum or Copper) includes, for example, impact extrusion and coining techniques. In some embodiments, the heat sink can be an integral portion of the substrate. The Aluminum substrate can be anodized to produce aluminum oxide dielectric layer surface on which electrically conductive traces can be fabricated. In the case of a Copper substrate, a polymer such as polyimide or a glass dielectric layer may be coated on the surface first before electrical conductive traces are printed. Alternatively, the substrate can be an insert-molded lead-frame with thermally conductive plastic. Finally, a reflector may be attached to the substrate by heat-staking, in the case of plastic reflector or by forming in the case of metal reflector.

In a third embodiment of the present invention, an apparatus includes a board and a light emitting apparatus mounted on or within the board. The board has a front surface and a back surface, and the board defines an opening. Further, the board has electrically conductive connection traces on its back surface. The light emitting apparatus is mounted within the opening of the board. The light emitting apparatus includes a substrate, a plurality of conductive traces, a reflector, and at least one photonic device. The substrate has a top surface and a bottom surface, a portion of the top surface defining a mounting pad. The conductive traces is on the top surface of the substrate, the conductive traces extending from the mounting pad to a side edge of the substrate and the conductive traces comprising electrically conductive material. The reflector is attached to the top surface of the substrate, the reflector surrounding the mounting pad while leaving other portions of the top surface of the substrate and portions of the conductive traces exposed, the reflector defining an optical cavity. The photonic device is attached to the substrate at the mounting pad, the photonic device connected to at least one conductive trace. At least one conductive trace of at least one light emitting apparatus is aligned with at least one connection trace of the board.

The light emitting apparatus is mounted on the board using surface mount technology. The light emitting apparatus is mounted on the board with a mounting medium such as, for example, solder, epoxy, and connector.

Other aspects and advantages of the present invention will become apparent from the following detailed description, taken in conjunction with the accompanying drawings, illustrating by way of example the principles of the invention.

### BRIEF DESCRIPTION OF THE DRAWINGS

FIG. 1 is a perspective view of an apparatus in accordance with one embodiment of the present invention;

FIG. 2 is an exploded perspective view of the apparatus of FIG. 1;

FIG. 3A is a top view of the apparatus of FIG. 1;

FIG. 3B is a side view of the apparatus of FIG. 1;

FIG. 3C is a bottom view of the apparatus of FIG. 1;

FIG. 3D is a cross-sectional view of the apparatus of FIG. 1 sans its lens, cut along the line 3D-3D in FIG. 3A;

FIG. 4 is a flowchart illustrating another aspect of the present invention;

FIG. 5A is a perspective view of an apparatus in accordance with another embodiment of the present invention; and

FIG. 5B is a bottom view of the apparatus illustrated in FIG. 5A.

### DETAILED DESCRIPTION

Introduction

The present invention will now be described with reference to the FIGS. 1 through 5B, which illustrate various embodiments of the present invention. As illustrated in the Figures, some sizes of structures or portions are exaggerated relative to other structures or portions for illustrative purposes and, thus, are provided to illustrate the general structures of the present invention. Furthermore, various aspects of the present invention are described with reference to a structure or a portion being formed on other structures, portions, or both. As will be appreciated by those of skill in the art, references to a structure being formed “on” or “above” another structure or portion contemplates that additional structure, portion, or both may intervene. References to a structure or a portion being formed “on” another structure or portion without an intervening structure or portion are described herein as being formed “directly on” the structure or portion.

Furthermore, relative terms such as “on” or “above” are used herein to describe one structure's or portion's relationship to another structure or portion as illustrated in the Figures. It will be understood that relative terms such as “on” or “above” are intended to encompass different orientations of the device in addition to the orientation depicted in the Figures. For example, if the device in the Figures is turned over, structure or portion described as “above” other structures or portions would now be oriented “below” the other structures or portions. Likewise, if the device in the Figures is rotated along an axis, stricture or portion described as “above” other structures or portions would now be oriented “next to” or “left of” the other structures or portions. Like numbers refer to like elements throughout.

The present invention will now be described with reference to the FIGS. 1A through 5B, which illustrate various embodiments of the present invention. In one embodiment of the present invention, a light emitting apparatus includes a substrate, a plurality of conductive traces on the substrate, a reflector attached to the substrate, a least one photonic device on the substrate, and heat sink attached to the substrate. The substrate has a top surface and a bottom surface, a portion of the top surface defining a mounting pad. The conductive traces are on the top surface of the substrate, the conductive traces extending from the mounting pad to a side edge of the substrate and the conductive traces including electrically conductive material. The reflector is attached to the top surface of the substrate, the reflector surrounding the mounting pad while leaving other portions of the top surface of the substrate and potions of the conductive traces exposed, the reflector partially defining an optical cavity. The photonic device is attached to at least one conductive trace at the mounting pad. The heat sink is attached to the bottom surface or an integral portion of the substrate.

This light emitting apparatus can be mounted on a board, for example printed circuit board (PCB) with an opening and connection traces on the bottom side of the PCB. The light emitting apparatus can be mounted on the bottom of the PCB facing up (that is, with the lens side facing toward the top side of the PCB). Further, the connection traces on the bottom side of the PCB can be aligned with the conductive traces on the top surface of the light emitting apparatus to provide electrical connection. The connection may be achieved by solder reflow of SMT (Surface Mount Technology).

With this design, thermal energy generated by the light emitting apparatus is not trapped between the PCB and the optical or electrical panel. Instead, thermal energy is dissipated by the thermal cooling fins of the heat sink that is attached to or an integral portion of the substrate. As illustrated in the Figures, the substrate is top-mounted to the PCB, by for example, by Surface Mount Technology method. Further, its heat sink portion rises from the surface of the board into free space where effective and efficient air cooling by convection or forced convection can be accomplished.

Light Emitting Apparatus

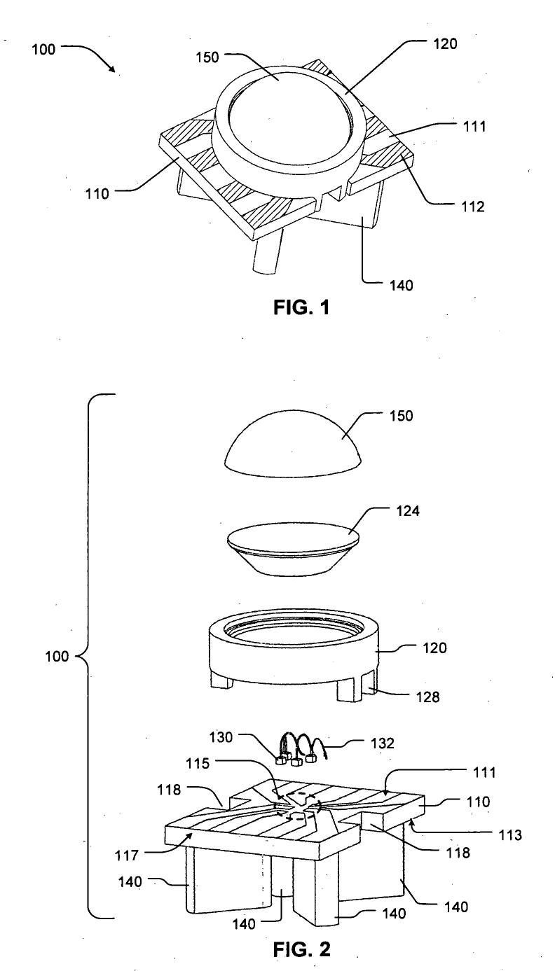

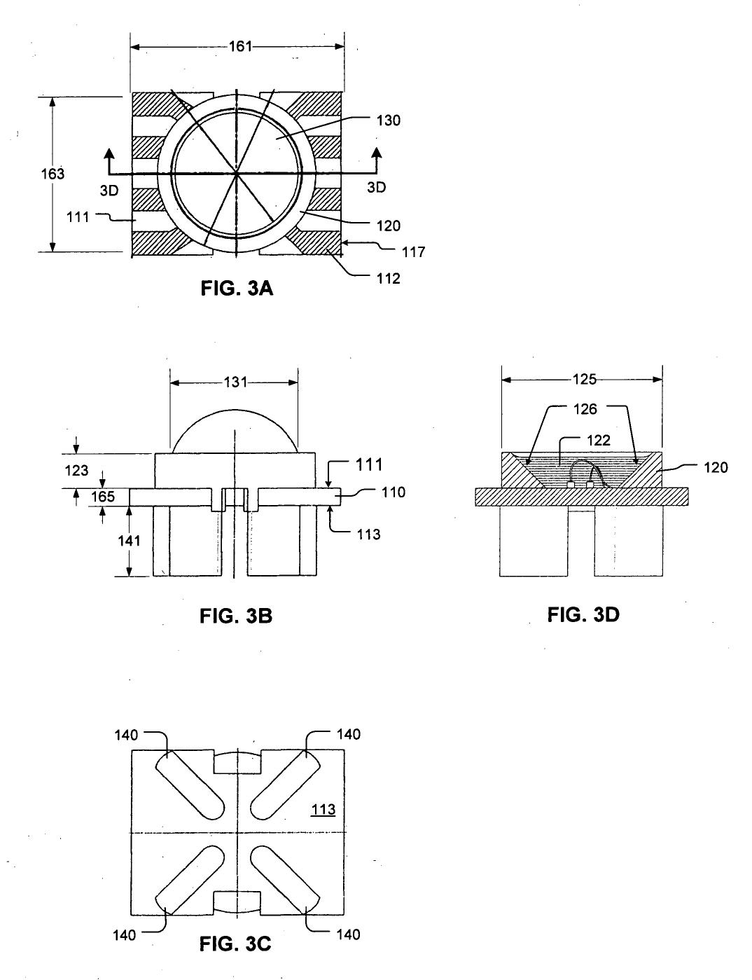

FIG. 1 is a perspective view of an apparatus 100 in accordance with one embodiment of the present invention. FIG. 2 is an exploded perspective view of the apparatus 100 of FIG. 1. FIGS. 3A, 3B, and 3D illustrate the top view, the side view, and the bottom view of the apparatus 100 of FIGS. 1 and 2. FIG. 3D is a cross sectional side view of the apparatus 100 of FIGS. 1 and 2 less its lens, cut along line 3D-3D of FIG. 3A.

Substrate

Referring to FIGS. 1 through 3D, a light emitting apparatus 100 includes a substrate 110 having a top surface 111 and a bottom surface 113. A portion of the top surface 111 of the substrate 110 define a mounting pad 115. The substrate 110 is made of thermally conductive material, for example, Aluminum (Al) or Copper (Cu). If aluminum is used, the substrate 110 is anodized to form a dielectric surface coating of Aluminum oxide. Anodization of the substrate 110 produces aluminum oxide layer of approximately 0.001 to 0.002 inches thick on the surfaces of the substrate 110.

In an alternative embodiment, the substrate 110 is made of high temperature plastics such as, for example, Polypthalamide, Polyimide, Liquid Crystal Polymer (LCP) which are filled with thermal conductive materials such as graphite or optical materials such as Titinium dioxide, or any combination of these.

In the illustrated embodiment, the top surface 111 is optically reflective such that any light generated from a photonic device 130 is reflected away from the top surface 111. Physical dimensions of the substrate 110 can vary widely depending on the desired characteristic of the apparatus 100 and can range in the order of millimeters, centimeters, or even larger. In the illustrated embodiment, the substrate 110 has a length 161 of approximately nine millimeters, a width 163 of approximately seven millimeters, and a height 165 of approximately 0.5 millimeters to one millimeter.

Traces

A plurality of conductive traces 112 are on the top surface 111 of the substrate 110. As illustrated, the conductive traces 112 extend from the mounting pad 115 to side edges 117 of the substrate 110. The conductive traces 112 are made of electrically conductive material such as, for example, silver (Ag) ink. To avoid clutter, not all traces illustrated in the Figures are designated with reference number 112. The silver ink can be a polymer ink, for example, Ag-load polymer ink, or a thick film ink, for example, DuPont's Ag ink number 7713 which is fired at 500 degrees Celsius. The traces 112 on the top surface 11 of the substrate 110 can be fabricated using screen or pad printing if the ink is in the form of paste, or jet printing if the ink is in the form of liquid. Then, ink is allowed to bond on to the surface at elevated temperatures, for example, similar to surface mount reflow technique.

Reflector

A reflector 120 is attached to the top surface 111 of the substrate 110. The reflector 120 covers portions of the top surface 111 (including portions of the conductive traces 112) of the substrate 110 while leaving other portions exposed. The reflector 120 generally surrounds the mounting pad 115. The reflector 120 has generally a cylindrical shape and defines an opening that, combined with other portions of the apparatus 100, defines an optical cavity 122 as illustrated. That is, the reflector 120 partially defines an optical cavity 122 which it surrounds. As more clearly illustrated in FIG. 3D, the reflector 120 includes a sloped surface 126 that surrounds the optical cavity 122. The sloped surface 126 is specular finished or polished to reflect light from the photonic device 130 in a desired direction. An alternative embodiment, the sloped surface 126 may include diffusion grating to diffuse light from the photonic device 130.

Physical dimensions of the reflector 120 can vary widely depending on the desired characteristic of the apparatus 100 and can range in the order of fractions of millimeters or even larger. In the illustrated embodiment, the reflector 120 has a height 123 of approximately two to four millimeters and an outer diameter 125 of approximately seven millimeters.

LED Chip

At least one photonic device 130 is attached to at least one conductive trace 112 at the mounting pad 115. The photonic device 130 can be, for example, a light emitting diode (LED) chip or a laser. The photonic device 130 can also be attached to other traces using bond wire 132. LEDs are semiconductor diodes that typically emit a light when exited with electrical current. A variety of colors can be generated based on the material used for the LEDs. Common materials used in LEDs are, for example only:

Aluminum indium gallium phosphide (AlInGaP);

Indium gallium nitride (InGaN);

Aluminum gallium arsenide (AlGaAs);

Gallium phosphide (GaP);

Indium gallium nitride (InGaN);

Indium gallium aluminum phosphide;

Silicon carbide (SiC).

Encapsulant

The optical cavity 122 can be filled with encapsulant material illustrated with reference numeral 124 in FIG. 2. The encapsulant material is injected into the optical cavity 122 wherein it encases the photonic device 130, fills the optical cavity 122, and solidifies. The solidified form of the encapsulant material is illustrated in FIG. 2 with reference numeral 124. The encapsulant 124 can be optically clear silicone epoxy. However, in some applications, the encapsulant 124 may include diffusants, phosphors, or both to achieve desired uniformity of light intensity, color rendering, or both. For example, the encapsulant 124 may include particles of Titanium Dioxide, Barium Sulfate to diffuse light from the photonic device 130. The phosphors include material that absorbs light having a first wavelength and emit light having a second wavelength. For example, yellow phosphors absorb blue light and re-emit yellow light.

Lens

A lens 150 can be placed on the reflector 120, on the encapsulant 124, or both. The lens is in contact with the encapsulant 124 which, in turn, is in contact with the photonic device 130. Accordingly, the lens 150 is optically coupled to the photonic device 130. The lens 150 is configured to perform imaging operations on the light from the photonic device 130 such as, for example, refracting the light to achieve a desired radiation pattern.

The lens 150 can be optically clear material such as glass or clear plastic. However, in some applications, the lens 150 may include diffusants, phosphors, or both to achieve desired uniform light intensity, color rendering, or both. For example, the lens 150 may include particles of Titanium Dioxide, Barium Sulfate to diffuse light from the photonic device 130. The phosphors include material that absorbs light having a first wavelength and emit light having a second wavelength.

Heat Sink

A heat sink 140 is attached to the bottom surface 113 or an integral portion of the substrate 110. In the illustrated embodiment, the heat sink 140 includes four heat dissipating fins 140. In other embodiments, the heat sink 140 can be implemented in variety of shapes and sizes. For example, the heat sink 140 can include fins of any shape, slots, or both for increased surface area leading to higher heat dissipation. The heat sink 140 is made of thermally conductive materials such as, for example, metal or thermal conductive plastics

Method

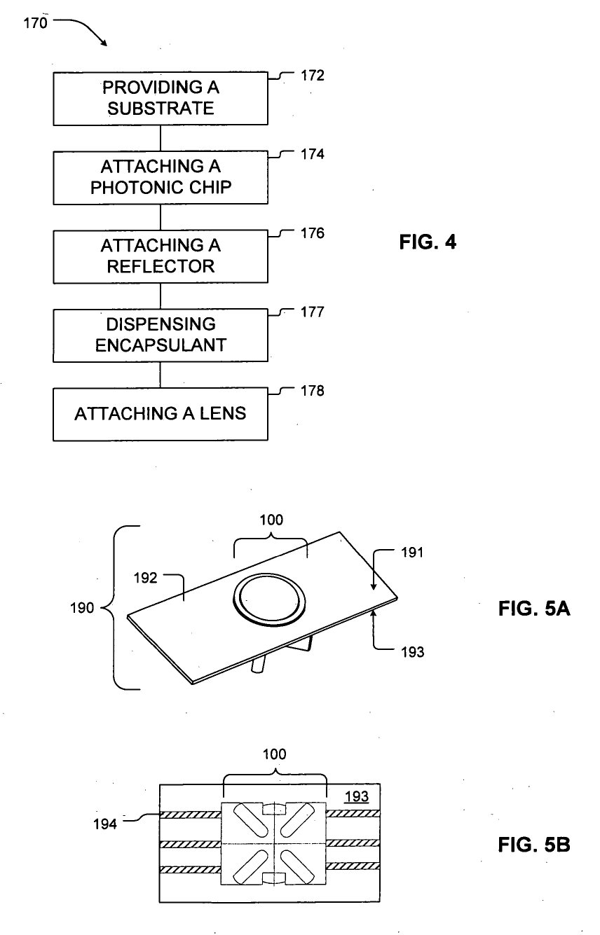

FIG. 4 is a flowchart 170 illustrating the method of fabricating an apparatus such as, for example, the light emitting apparatus 100 of FIG. 1. Referring to FIGS. 2 and 4, first, the substrate 110 having the top surface 111 and the bottom surface 113 is provided. A portion 115 of the top surface 111 defines a mounting pad 115. The substrate 110 has conductive traces 112 on its top surface 111. Step 172. Then, at least one photonic device 130 is attached on the mounting pad 115, the photonic device in contact with at least one conductive trace 112. Step 174. Then, the reflector 120 is attached on the top surface 111 of the substrate 110. The reflector 120 surrounds the mounting pad 115 and partially defines the optical cavity 122 (illustrated in FIG. 3D). Step 176. Further, the encapsulant 124 is dispensed into the cavity 122. Step 177. Finally, and optionally, the lens 150 is attached. Step 187.

The substrate 110 can be manufactured using a variety of know techniques including, for example only, impact extrusion, coining, or molding techniques. For the impact extrusion technique, usually a small shot of solid material (such as Aluminum) is placed in a die and is impacted by a ram, which causes cold flow in the material. Further, the substrate 110 can be anodized to form a dielectric surface coating of Aluminum oxide. Alternatively, the substrate 110 is manufactured by insert-molding of metal lead frame with thermally conductive plastic.

The heat sink 140 can be formed as an integral component of the substrate 110 during the manufacturing process of the substrate 110 such as, for example, during the impact extrusion process. Alternatively, the heat sink 140 can be fabricated as a separate component and attached to the substrate 110.

The reflector 120 can be attached to the substrate 110 using a number of techniques, for example, the heat staking technique. In the heat staking technique, studs 128 protruding from the reflector 120 is fitted into gaps 118 of the substrate 110. Then, the pressure and heat are used to stake, swage, or seal the reflector 120 with the substrate 110 wherein a secure engagement of these parts are achieved. This is a versatile technique allowing efficient and secure mechanical joining of dissimilar materials. The photonic device 130 makes an electrical contact with at least one of the conductive traces 112 in a direct contact, via the bond wire 132, or both. The bond wire 132 is bonded on the photonic device 130 and the conductive trace 112. The optical cavity 122 can be filled with the encapsulant 124. The lens 150 can then be attached to the reflector 120, the encapsulant 124, or both.

Board with LED Module

FIG. 5A is a perspective view of an apparatus 190 in accordance with another embodiment of the present invention. FIG. 5B is a bottom view of the apparatus 190 of FIG. 5A. Referring to FIGS. 5A and 5B, the light emitting apparatus 100 (having the same construction as the light emitting apparatus 100 of FIGS. 1 to 3D) is mounted within an opening of a PCB (Printed circuit Board) 192 such as, for example, printed circuit board (PCB) 192. The board 192 has a front surface 191 and a back surface 193 with connection traces 194 on the back surface 193. When the light emitting apparatus 100 is mounted within the opening, at least one conductive trace 112 (illustrated in FIGS. 1, 2, and 3A) is aligned with at least one connection trace 194 of the board 192 thus making an electrical connection. Further, the conductive traces 112 on the top surface 11 of the substrate 110 can be soldered to trace 194 of the board 192 using, for example, surface mount reflow technique. The light emitting apparatus 100 may be further secured to the board 190 with a mounting medium such as, for example, solder, epoxy, or connector. In the assembly, light is emitted in the directions away from the top surface of 192 which may not contain any electrical circuit but may be coated with optically reflective materials to form a mirror—a feature accomplished only by the invention.

### CONCLUSION

From the foregoing, it will be apparent that the present invention is novel and offers advantages over the current art. Although specific embodiments of the invention are described and illustrated above, the invention is not to be limited to the specific forms or arrangements of parts so described and illustrated. For example, differing configurations, sizes, or materials may be used to practice the present invention. The invention is limited by the claims that follow.

What is claimed is:

1. An apparatus comprising:
a substrate having a top surface and a bottom surface, a portion of the top surface defining a mounting pad;
a plurality of conductive traces on the top surface of said substrate, said conductive traces extending from the mounting pad to a side edge of said substrate and said conductive traces comprising electrically conductive material;
a reflector attached to the top surface of said substrate, said reflector surrounding the mounting pad while leaving other portions of the top surface of said substrate and potions of the conductive traces exposed, said reflector partially defining an optical cavity;
at least one photonic device attached to at least one conductive trace at the mounting pad; and
a heat sink attached to the bottom surface of said substrate.

2. The apparatus recited in claim 1 wherein the photonic device is at least one of light emitting diode (LED) and laser.

3. The apparatus recited in claim 1 wherein the substrate comprises thermally conductive material.

4. The apparatus recited in claim 1 wherein the substrate comprises material selected from a group consisting of Aluminum (Al) and Copper (Cu) and further comprising a dielectric layer between said substrate and said conductive traces.

5. The apparatus recited in claim 5 wherein the dielectric layer comprises material selected from a group consisting of glass coating, polymer, and anodized substrate material.

6. The apparatus recited in claim 1 wherein said photonic device is wire bonded to at least one conductive trace.

7. The apparatus recited in claim 1 further comprising encapsulant filling the optical cavity.

8. The apparatus recited in claim 7 further comprising a lens in contact with said encapsulant thereby optically coupled to the photonic device.

9. The apparatus recited in claim 7 further wherein said encapsulant comprises at least one of diffusants and phosphors.

10. The apparatus recited in claim 7 further wherein said encapsulant comprises material selected from a group consisting of Titanium dioxide, Barium Sulfate.

11. The apparatus recited in claim 7 further wherein said encapsulant comprises phosphor material that absorbs light having a first wavelength and emit light having a second wavelength.

12. The apparatus recited in claim 1 wherein the top surface is optically reflective.

13. The apparatus recited in claim 1 wherein said reflector includes an optically reflective surface surrounding the optical cavity.

14. The apparatus recited in claim 13 wherein the optically reflective surface has diffusion grating.

15. The apparatus recited in claim 1 wherein the top surface comprises aluminum oxide.

16. The apparatus recited in claim 1 wherein said conductive traces comprise silver.

17. The apparatus recited in claim 1 wherein the substrate comprises plastic.

18. The apparatus recited in claim 17 wherein the substrate comprises material selected from a group consisting of Polyphthalamide Polyimide, and Liquid Crystal Polymer filled with thermal conductive material such as graphite or ceramics or optical reflective material such as Titanium Dioxide.

19. A method of fabricating an apparatus, the method comprising:
providing a substrate having a top surface and a bottom surface, a portion of the top surface defining a mounting pad, the substrate having conductive traces on the top surface;
attaching at least one photonic device on the mounting pad, the photonic device in contact with at least one conductive trace; and
attaching a reflector on the top surface of the substrate, the reflector surrounding the mounting pad and partially defining an optical cavity.

20. The method recited in claim 19 further comprising:
forming a heat sink to the bottom surface of the substrate; and
filling the optical cavity with encapsulant.

21. The method recited in claim 20 further comprising attaching a lens on the reflector.

22. The method recited in claim 19 wherein the step of providing the substrate comprises manufacturing the substrate using coining or impact extrusion technique.

23. The method recited in claim 19 wherein a heat sink is integrally manufactured as part of the substrate during the coining or impact extrusion process.

24. The method recited in claim 23 wherein the heat sink comprises cooling fins.

25. The method recited in claim 19 wherein the step of attaching the reflector includes heat-staking the reflector to said substrate.

26. The method recited in claim 19 wherein the substrate is anodized to produce aluminum oxide layer surface.

27. The method recited in claim 19 wherein the substrate is insert-molded lead-frame with thermally conductive plastic.

28. An apparatus comprising:
a board having a front surface and a back surface, said board defining an opening, and said board having electrically conductive connection traces on its back surface;
a light emitting apparatus mounted within the opening of said board wherein the light emitting apparatus comprises:
a substrate having a top surface and a bottom surface, a portion of the top surface defining a mounting pad;
a plurality of conductive traces on the top surface of said substrate, said conductive traces extending from the mounting pad to a side edge of said substrate and said conductive traces comprising electrically conductive material;
a reflector attached to the top surface of said substrate, said reflector surrounding the mounting pad while leaving other portions of the top surface of said substrate and potions of the conductive traces exposed, said reflector defining an optical cavity;
at least one photonic device attached to the substrate at the mounting pad, the photonic device connected to at least one conductive trace; and
wherein at least one conductive trace of at least one light emitting apparatus is aligned with at least one connection trace of said board.

29. The apparatus recited in claim 28 wherein the light emitting apparatus is mounted on said board using surface mount technology.

30. The apparatus recited in claim 28 wherein the light emitting apparatus is mounted on said board with a mounting medium.

31. The apparatus recited in claim 30 wherein the mounting medium is selected from a group consisting of solder, epoxy, and connector.
